(19) United States
(12) Patent Application Publication
(10) Pub. No.: US 2021/0167307 A1
(43) Pub. Date: Jun. 3, 2021

(54) TWO-DIMENSIONAL RUDDLESDEN-POPPER HYBRID PEROVSKITE FILM WITH A GRADIENT STRUCTURAL CHARACTERISTIC AND METHOD FOR PREPARING THE SAME

(71) Applicant: ZHEJIANG UNIVERSITY, Hangzhou City (CN)

(72) Inventors: Gang WU, Hangzhou City (CN); Xiaomei LIAN, Hangzhou City (CN); Jiehuan CHEN, Hangzhou City (CN); Hongzheng CHEN, Hangzhou City (CN)

(21) Appl. No.: 17/149,761

(22) Filed: Jan. 15, 2021

Related U.S. Application Data
(63) Continuation of application No. PCT/CN2019/098047, filed on Jul. 26, 2019.

(30) Foreign Application Priority Data
Apr. 11, 2019 (CN) 201910289614.9

(51) Int. Cl. H01L 51/42; H01L 51/00

(52) U.S. Cl. CPC H01L 51/4213; H01L 51/0026; H01L 51/0003

(57) ABSTRACT

The present invention discloses a two-dimensional Ruddlesden-Popper hybrid perovskite film with a gradient structural characteristic and a preparation method thereof, belonging to the field of organic-inorganic hybrid perovskite materials. The film can be obtained by deposition from a precursor solution containing two spacer cations by a solution spin-coating method. The film is composed of large orientedly grown grains, has a high quality and good carrier transmission characteristics, and has a gradient structural characteristic with one of the spacer cations being enriched on the film surface, which is beneficial to obtain good moisture resistance stability. This is of great significance for the preparation of high-performance hybrid perovskite photoelectric devices by a solution method.

### CROSS-REFERENCE TO RELATED APPLICATIONS

The present application is a continuation of International Patent Application No. PCT/CN2019/098047, filed on Jul. 26, 2019, which claims priority to Chinese patent application NO. 2019102896149, filed on Apr. 11, 2019, the entire contents of which are incorporated herein by their references.

### TECHNICAL FIELD

The present invention belongs to the field of organic-inorganic hybrid perovskite materials, and specifically relates to a two-dimensional Ruddlesden-Popper hybrid perovskite film with a gradient structural characteristic and a method for preparing the same.

### BACKGROUND

In recent years, three-dimensional organic-inorganic hybrid perovskite materials have developed rapidly, and the highest efficiency of solar cells prepared from three-dimensional organic-inorganic hybrid perovskite materials has exceeded 23%. At present, more and more attention has been paid to the stability of perovskite batteries. Two-dimensional perovskite has a better wet stability than three-dimensional perovskite because it contains hydrophobic spacer cations.

However, the spacer cations will form an insulating layer in the two-dimensional perovskite, which hinders transmission of the carriers. Moreover, the existence of spacer cations will also limit the growth of grains, resulting in the increase of grain boundaries in the two-dimensional perovskite films, which will lead to serious recombination of carriers and further deteriorate the performance of optoelectronic devices. At present, the main way to avoid the barrier of carrier transmission caused by the spacer cationic insulating layer is to make the crystals in a two-dimensional perovskite film be oriented and grow vertically to the substrate. The main ways to achieve this are high temperature (>100° C.) thermal spin-coating, using mixed solvents (such as DMF and DMSO) and adding volatile additives (such as ammonium thiocyanate). In the two-dimensional perovskite films obtained by the above method, the distribution of spacer cations is characterized by decreasing upward in the thickness direction. Considering the hydrophobic property of spacer cations, the enrichment of spacer cations on the surface of perovskite will be more beneficial to improve the wet stability of the films. Therefore, a two-dimensional hybrid perovskite film with both high charge transport capacity and high moisture resistance should have the following characteristics: 1. the film is composed of large grains orientedly grown perpendicular to the substrate; and 2. spacer cations are enriched on the upper surface, and the concentration distribution decreases downward along the thickness direction of the film. At present, there is still no method to prepare two-dimensional perovskite films with the above structure.

### SUMMARY

The purpose of the present invention is to solve the above problems in the prior art, and to provide a two-dimensional Ruddlesden-Popper hybrid perovskite film with a gradient structure. The film is composed of large orientedly grown grains, which has good carrier transmission characteristics, and has a gradient structure characteristic with one of spacer cations being enriched on the film surface, which is beneficial to obtain good moisture resistance stability.

The specific technical solution adopted by the present invention is as follows:

A two-dimensional Ruddlesden-Popper hybrid perovskite film with a gradient structural characteristic, wherein the film is obtained by depositing a precursor solution containing two spacer cations, and one of the two spacer cations is n-butyl ammonium, and a second spacer cation is phenylethyl ammonium, benzyl ammonium, t-butyl ammonium, imidazolyl ammonium, ethylpyridyl ammonium or isobutyl ammonium; and the second spacer cation is enriched on a surface of the film, forming a concentration gradient which decreases downwards along a thickness direction of the film.

It should be noted that n-butyl ammonium, phenylethyl ammonium, benzyl ammonium, t-butyl ammonium, imidazolyl ammonium, ethylpyridyl ammonium and isobutyl ammonium described herein in the present invention all refer to cations of corresponding compounds.

On the basis of this solution, the present invention can further provide one or more of the following preferred embodiments. It should be pointed out that the technical features of each preferred embodiment in the present invention can be combined accordingly on the premise of no conflict with each other.

Preferably, in the precursor solution, a molar ratio of the n-butyl ammonium to the second spacer cation is 1:0.01-0.3.

Preferably, the precursor solution is a mixture of methylamine hydroiodide, hydroiodides of the two spacer cations, lead iodide and an organic solvent, and the organic solvent is one of or a mixture of more than one of formamide, dimethyl sulfoxide, or N,N-dimethylformamide.

Preferably, in the precursor solution, a ratio of the lead iodide to the organic solvent is 50-800 mg: 1 mL.

Preferably, in the precursor solution, a molar ratio of the hydroiodides of the two spacer cations:the methylamine hydroiodide:the lead iodide is 2:2:3 or 2:3:4 or 2:4:5.

Preferably, the deposition specifically includes: spin-coating the precursor solution on a substrate to form a film, and annealing.

Preferably, a temperature of the substrate is 25-70° C., and a temperature of the precursor solution is the same as that of the substrate.

Preferably, a temperature range for the annealing is 70-150° C., and a time range for the annealing is 5-20 min.

Preferably, the substrate is an ITO glass substrate on which a PEDOT:PSS layer is spin-coated.

Another object of the present invention is to provide a method for preparing a two-dimensional Ruddlesden-Popper hybrid perovskite film with a gradient structural characteristic, the method comprising the following steps of:

firstly, preparing an ITO glass substrate on which a PEDOT:PSS layer is spin-coated;

subsequently, mixing hydroiodides of two spacer cations, methylamine hydroiodide and lead iodide with an organic solvent to obtain a precursor solution, wherein, one of the two spacer cations is n-butyl ammonium, and a second spacer cation of the two spacer cations is phenylethyl ammonium, benzyl ammonium, t-butyl ammonium, or isobutyl ammonium, a molar ratio of the n-butyl ammonium to the second spacer cation is 1:0.01-0.3, a ratio of the lead iodide to the organic solvent is 50-800 mg: 1 mL, the organic solvent is one of or a mixture of more than one of formamide, dimethyl sulfoxide, or N,N-dimethylformamide, and a molar ratio of the hydroiodides of the two spacer cations:the methylamine hydroiodide: the lead iodide is 2:2:3 or 2:3:4 or 2:4:5; and

finally, spin-coating the precursor solution on the substrate to form a film, and annealing, wherein, during the spin-coating, a temperature of the substrate is 25-70° C., a temperature of the precursor solution used for the spin-coating is the same as that of the substrate, a temperature range for the annealing is 70-150° C., and a time range for the annealing is 5-20 min.

According to the invention, on the one hand, a two-dimensional hybrid Ruddlesden-Popper hybrid perovskite film composed of large orientedly grown grains is obtained through deposition using a perovskite precursor solution containing two types of spacer cations, so that good carrier transmission capability is obtained; on the other hand, one of the two types of spacer cations can be enriched on the film surface, forming a concentration gradient decreasing downward in the thickness direction, which is beneficial to obtain good moisture resistance stability. It is of great significance for the preparation of high-performance hybrid perovskite photoelectric devices by a solution method.

### BRIEF DESCRIPTION OF DRAWINGS

FIG. 1 illustrates a cross-sectional SEM diagram of a two-dimensional Ruddlesden-Popper hybrid perovskite film with a gradient structure.

FIG. 2 illustrates Time of Flight-Secondary Ion Mass Spectrometry (TOF-SIMS) data of the distribution of phenylethyl ammonium cations in the film, with the upper surface of the film on the left and the lower surface of the film on the right.

FIG. 3 illustrates the change of X-ray diffraction (XRD) pattern of a two-dimensional Ruddlesden-Popper hybrid perovskite film stored in air with humidity of 50±5% with storage time (0 days to 120 days).

### DESCRIPTION OF EMBODIMENTS

The preparation process of a two-dimensional Ruddlesden-Popper hybrid perovskite film with a characteristic of a gradient structure is as follows: firstly, an ITO glass substrate is ultrasonically washed with a detergent, acetone, isopropanol and ethanol respectively for 5 minutes, then rinsed with deionized water and dried; after UV-ozone treatment, a PEDOT:PSS layer with a thickness of about 25 nm is prepared by spin-coating, baked at 140° C. for 15 minutes and then taken out; hydroiodates of two spacer cations, methylamine hydroiodide and lead iodide are mixed with an organic solvent, wherein one of the two spacer cations is n-butyl ammonium, and the second spacer cation is phenylethyl ammonium, benzyl ammonium, t-butyl ammonium, or isobutyl ammonium, wherein, the molar ratio of the the n-butyl ammonium to the second spacer cation is 1:0.01-0.3, the ratio of lead iodide to the organic solvent is 50-800 mg: 1 mL, the organic solvent is one of or a mixture of formamide, dimethyl sulfoxide, N,N-dimethylformamide, and the molar ratio of the hydroiodides of the two spacer cations:themethylamine hydroiodide: the lead iodide is 2:2:3 or 2:3:4 or 2:4:5; and then the precursor solution is spin-coated on the substrate to form a film, and annealing is carried out, wherein the temperature of the substrate is 25-70° C., the temperature of the precursor solution for spin-coating is the same as that of the substrate, the annealing temperature range is 70-150° C., and the annealing time range is 5-20 min.

Based on the above preparation method, the present invention will be further detailed by the following examples:

### Example 1

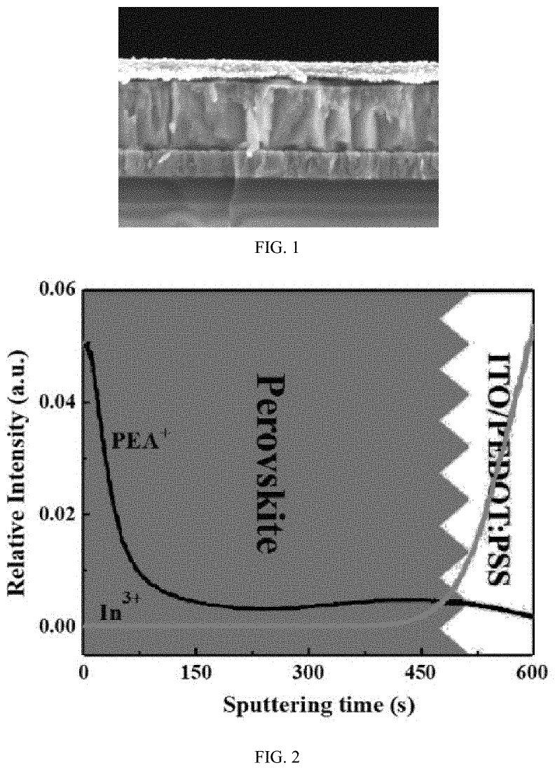

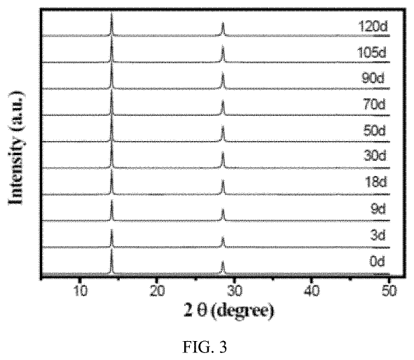

An ITO glass substrate was ultrasonically washed with a detergent, acetone, isopropanol and ethanol respectively for 5 minutes, then rinsed with deionized water and dried. The dried ITO glass substrate was treated by UV-ozone, spin-coated with a PEDOT:PSS layer with a thickness of about 25 nm, baked at 140° C. for 15 minutes and then taken out. Phenethylamine hydroiodide, n-butylamine hydroiodide, methylamine hydroiodide and lead iodide were mixed and dissolved in N,N-dimethylformamide, wherein, the ratio of lead iodide to N,N-dimethylformamide was 50 mg: 1 mL, and the molar ratio of (n-butylamine hydroiodide+phenethylamine hydroiodide):methylamine hydroiodide:lead iodide is 2:2:3, an ion molar ratio of n-butyl ammonium:phenylethyl ammonium was 1:0.01. A precursor solution was obtained by stirring overnight. A two-dimensional Ruddlesden-Popper hybrid perovskite film with a gradient structure and high quality was obtained by spin-coating the precursor solution at 25° C. on the ITO glass substrate covered by PEDOT:PSS at 25° C. and annealing for 5 minutes at 70° C. The scanning electron microscope (SEM) photograph of the cross section of the film is shown in FIG. 1, which shows that the film is composed of large grains orientedly grown along the thickness direction. FIG. 2 illustrates the Time of Flight-Secondary Ion Mass Spectrometry (TOF-SIMS) data, which shows that the concentration distributions of two spacer cations in the perovskite film are different, in which phenylethyl ammonium cations PEA+ are enriched on the surface, that is, the PEA+ concentration on the surface of the film is the highest, and a concentration gradient that decreases downwards along the thickness direction is formed. The stability test in FIG. 3 shows that the X-ray diffraction (XRD) pattern of the film is almost unchanged after being stored in the air with a humidity of 50±5% for 120 days, thus showing good humidity resistance stability.

### Example 2

An ITO glass substrate was ultrasonically washed with a detergent, acetone, isopropanol and ethanol respectively for 5 minutes, then rinsed with deionized water and dried. The dried ITO glass substrate was treated by UV-ozone, spin-coated with a PEDOT:PSS layer with a thickness of about 25 nm, baked at 140° C. for 15 minutes and then taken out. Benzylamine hydroiodide, n-butylamine hydroiodide, methylamine hydroiodide and lead iodide were mixed and dissolved in formamide, wherein, the ratio of lead iodide to formamide was 800 mg:1 mL, the molar ratio of (n-butylamine hydroiodide+benzylamine hydroiodide):methylamine hydroiodide:lead iodide was 2:4:5, and an ion molar ratio of n-butyl ammonium:benzyl ammonium was 1:0.3. A precursor solution was obtained by stirring overnight. A two-dimensional Ruddlesden-Popper hybrid perovskite film with a gradient structure and high quality was obtained by spin-coating the precursor solution at 30° C. on the ITO glass substrate covered by PEDOT:PSS at 30° C. and annealing was carried out at 150° C. for 20 minutes. The cross-sectional morphology of the film was investigated and a scanning electron microscope (SEM) photograph similar to that in FIG. 1 was obtained. The Time of Flight Secondary-Ion Mass Spectrometry (TOF-SIMS) was investigated, and the obtained distribution data of benzyl ammonium was similar to that in FIG. 2. FIG. 1 and FIG. 2 show that a high-quality two-dimensional Ruddlesden-Popper hybrid perovskite film with a gradient structure is formed. The stability of the film after 120-day storage in air with a humidity of 50±5% was investigated. The X-ray diffraction (XRD) pattern of the film was similar to that in FIG. 3, demonstrating its good moisture resistance stability.

### Example 3

An ITO glass substrate was ultrasonically washed with a detergent, acetone, isopropanol and ethanol respectively for 5 minutes, then rinsed with deionized water and dried. The dried ITO glass substrate was treated by UV-ozone, spin-coated with a PEDOT:PSS layer with a thickness of about 25 nm, baked at 140° C. for 15 minutes and then taken out. T-butylamine hydroiodide, n-butylamine hydroiodide, methylamine hydroiodide and lead iodide were mixed and dissolved in dimethyl sulfoxide, wherein, the ratio of lead iodide to dimethyl sulfoxide was 400 mg:1 mL, the molar ratio of (n-butylamine hydroiodide+t-butylamine hydroiodide):methylamine hydroiodide:lead iodide was 2:3:4, and an ion molar ratio of n-butyl ammonium:t-butyl ammonium was 1:0.2. A precursor solution was obtained by stirring overnight. A two-dimensional Ruddlesden-Popper hybrid perovskite film with a gradient structure and high quality was obtained by spin-coating the precursor solution at 70° C. on the ITO glass substrate covered by PEDOT:PSS at 70° C. and annealing was carried out at 100° C. for 15 minutes. The cross-sectional morphology of the film was investigated and a scanning electron microscope (SEM) photograph similar to that in FIG. 1 was obtained. The Time of Flight Secondary-Ion Mass Spectrometry (TOF-SIMS) was investigated, and the obtained distribution data of t-butyl ammonium was similar to that in FIG. 2. FIG. 1 and FIG. 2 show that a high-quality two-dimensional Ruddlesden-Popper hybrid perovskite film with a gradient structure is formed. The stability of the film after 120-day storage in air with a humidity of 50±5% was investigated. The X-ray diffraction (XRD) pattern of the film was similar to that in FIG. 3, demonstrating its good moisture resistance stability.

### Example 4

An ITO glass substrate was ultrasonically washed with a detergent, acetone, isopropanol and ethanol respectively for 5 minutes, then rinsed with deionized water and dried. The dried ITO glass substrate was treated by UV-ozone, spin-coated with a PEDOT:PSS layer with a thickness of about 25 nm, baked at 140° C. for 15 minutes and then taken out. Isobutylamine hydroiodide, n-butylamine hydroiodide, methylamine hydroiodide and lead iodide were mixed and dissolved in N,N-dimethylformamide/dimethyl sulfoxide, wherein, the ratio of lead iodide to N,N-dimethylformamide/dimethyl sulfoxide was 600 mg: 1 mL, the molar ratio of (n-butylamine hydroiodide+isobutylamine hydroiodide):methylamine hydroiodide:lead iodide was 2:4:5, and an ion molar ratio of n-butyl ammonium:isobutyl ammonium was 1:0.1. A precursor solution was obtained by stirring overnight. A two-dimensional Ruddlesden-Popper hybrid perovskite film with a gradient structure and high quality was obtained by spin-coating the precursor solution at 60° C. on the ITO glass substrate covered by PEDOT:PSS at 60° C. and annealing carried out at 90° C. for 10 minutes. The cross-sectional morphology of the film was investigated and a scanning electron microscope (SEM) photograph similar to that in FIG. 1 was obtained. The Time of Flight Secondary-Ion Mass Spectrometry (TOF-SIMS) was investigated, and the obtained distribution data of isobutyl ammonium was similar to that in FIG. 2. FIG. 1 and FIG. 2 show that a high-quality two-dimensional Ruddlesden-Popper hybrid perovskite film with a gradient structure is formed. The stability of the film after 120-day storage in air with a humidity of 50±5% was investigated. The X-ray diffraction (XRD) pattern of the film was similar to that in FIG. 3, demonstrating its good moisture resistance stability.

### Example 5

An ITO glass substrate was ultrasonically washed with a detergent, acetone, isopropanol and ethanol respectively for 5 minutes, then rinsed with deionized water and dried. The dried ITO glass substrate was treated by UV-ozone, spin-coated with a PEDOT:PSS layer with a thickness of about 25 nm, baked at 140° C. for 15 minutes and then taken out. Imidazole hydroiodide, n-butylamine hydroiodide, methylamine hydroiodide and lead iodide were mixed and dissolved in N,N-dimethylformamide/formamide, wherein, the ratio of lead iodide to N,N-dimethylformamide/formamide was 300 mg: 1 mL, the molar ratio of (n-butylamine hydroiodide+imidazole hydroiodide):methylamine hydroiodide:lead iodide was 2:3:4, and an ion molar ratio of n-butyl ammonium:imidazolyl ammonium was 1:0.05. A precursor solution was obtained by stirring overnight. A two-dimensional Ruddlesden-Popper hybrid perovskite film with a gradient structure and high quality was obtained by spin-coating the precursor solution at 50° C. on the ITO glass substrate covered by PEDOT:PSS at 50° C. and annealing carried out at 120° C. for 12 minutes. The cross-sectional morphology of the film was investigated and a scanning electron microscope (SEM) photograph similar to that in FIG. 1 was obtained. The secondary ion mass spectrometry (SIMS) was investigated and shows that the distribution data of imidazolyl ammonium is similar to that in FIG. 2. FIG. 1 and FIG. 2 show that a high-quality two-dimensional Ruddlesden-Popper hybrid perovskite film with a gradient structure is formed.

### Example 6

An ITO glass substrate was ultrasonically washed with a detergent, acetone, isopropanol and ethanol respectively for 5 minutes, then rinsed with deionized water and dried. The dried ITO glass substrate was treated by UV-ozone, spin-coated with a PEDOT:PSS layer with a thickness of about 25 nm, baked at 140° C. for 15 minutes and then taken out. Ethylpyridine hydroiodide, n-butylamine hydroiodide, methylamine hydroiodide and lead iodide were mixed and dissolved in dimethyl sulfoxide/formamide, wherein, the ratio of lead iodide to dimethyl sulfoxide/formamide was 600 mg: 1 mL, the molar ratio of (n-butylamine hydroiodide+benzylamine hydroiodide):methylamine hydroiodide:lead iodide was 2:2:3, and an ion molar ratio of n-butyl ammonium:ethylpyridyl ammonium was 1:0.25. A precursor solution was obtained by stirring overnight. A two-dimensional Ruddlesden-Popper hybrid perovskite film with a gradient structure and high quality was obtained by spin-coating the precursor solution at 65° C. on the ITO glass substrate covered by PEDOT:PSS at 65° C. and annealing carried out at 130° C. for 10 minutes. The cross-sectional morphology of the film was investigated and a scanning electron microscope (SEM) photograph similar to that in FIG. 1 was obtained. The Time of Flight Secondary-Ion Mass Spectrometry (TOF-SIMS) was investigated, and the obtained distribution data of ethylpyridyl ammonium was similar to that in FIG. 2. FIG. 1 and FIG. 2 show that a high-quality two-dimensional Ruddlesden-Popper hybrid perovskite film with a gradient structure is formed. The stability of the film after 120-day storage in air with a humidity of 50±5% was investigated. The X-ray diffraction (XRD) pattern of the film was similar to that in FIG. 3, demonstrating its good moisture resistance stability.

### Example 7

An ITO glass substrate was ultrasonically washed with a detergent, acetone, isopropanol and ethanol respectively for 5 minutes, then rinsed with deionized water and dried. The dried ITO glass substrate was treated by UV-ozone, spin-coated with a PEDOT:PSS layer with a thickness of about 25 nm, baked at 140° C. for 15 minutes and then taken out. T-butylamine hydroiodide, n-butylamine hydroiodide, methylamine hydroiodide and lead iodide were mixed and dissolved in N,N-dimethylformamide/dimethyl sulfoxide/formamide, wherein, the ratio of lead iodide to N,N-dimethylformamide/dimethyl sulfoxide/formamide was 700 mg: 1 mL, the molar ratio of (n-butylamine hydroiodide+t-butylamine hydroiodide):methylamine hydroiodide:lead iodide was 2:4:5, and an ion molar ratio of n-butyl ammonium:phenylethyl ammonium was 1:0.2. A precursor solution was obtained by stirring overnight. A two-dimensional Ruddlesden-Popper hybrid perovskite film with a gradient structure and high quality was obtained by spin-coating the precursor solution at 55° C. on the ITO glass substrate covered by PEDOT:PSS at 55° C. and annealing carried out at 140° C. for 20 minutes. The cross-sectional morphology of the film was investigated and a scanning electron microscope (SEM) photograph similar to that in FIG. 1 was obtained. The Time of Flight Secondary-Ion Mass Spectrometry (TOF-SIMS) was investigated, and the obtained distribution data of t-butyl ammonium was similar to that in FIG. 2. FIG. 1 and FIG. 2 show that a high-quality two-dimensional Ruddlesden-Popper hybrid perovskite film with a gradient structure is formed. The stability of the film after 120-day storage in air with a humidity of 50±5% was investigated. The X-ray diffraction (XRD) pattern of the film was similar to that in FIG. 3, demonstrating its good moisture resistance stability.

### Example 8

An ITO glass substrate was ultrasonically washed with a detergent, acetone, isopropanol and ethanol respectively for 5 minutes, then rinsed with deionized water and dried. The dried ITO glass substrate was treated by UV-ozone, spin-coated with a PEDOT:PSS layer with a thickness of about 25 nm, baked at 140° C. for 15 minutes and then taken out. Phenylethylamine hydroiodide, n-butylamine hydroiodide, methylamine hydroiodide and lead iodide were mixed and dissolved in N,N-dimethylformamide, wherein, the ratio of lead iodide to N,N-dimethylformamide was 200 mg: 1 mL, the molar ratio of (n-butylamine hydroiodide+phenylethylamine hydroiodide):methylamine hydroiodide:lead iodide was 2:3:4, and an ion molar ratio of n-butyl ammonium:phenylethyl ammonium was 1:0.15. A precursor solution was obtained by stirring overnight. A two-dimensional Ruddlesden-Popper hybrid perovskite film with a gradient structure and high quality was obtained by spin-coating the precursor solution at 45° C. on the ITO glass substrate covered by PEDOT:PSS at 45° C. and annealing carried out at 150° C. for 15 minutes. The cross-sectional morphology of the film was investigated and a scanning electron microscope (SEM) photograph similar to that in FIG. 1 was obtained. The Time of Flight-Secondary Ion Mass Spectrometry (TOF-SIMS) was investigated, and the obtained distribution data of phenylethyl ammonium was similar to that in FIG. 2. FIG. 1 and FIG. 2 show that a high-quality two-dimensional Ruddlesden-Popper hybrid perovskite film with a gradient structure is formed. The stability of the film after 120-day storage in air with a humidity of 50±5% was investigated. The X-ray diffraction (XRD) pattern of the film was similar to that in FIG. 3, demonstrating its good moisture resistance stability.

What is claimed is:

1. A two-dimensional Ruddlesden-Popper hybrid perovskite film with a gradient structural characteristic, wherein the film is obtained by depositing a precursor solution containing two spacer cations, and one of the two spacer cations is n-butyl ammonium, and a second spacer cation is phenylethyl ammonium, benzyl ammonium, t-butyl ammonium, imidazolyl ammonium, ethylpyridyl ammonium or isobutyl ammonium; and the second spacer cation is enriched on a surface of the film, forming a concentration gradient which decreases downwards along a thickness direction of the film.

2. The two-dimensional Ruddlesden-Popper hybrid perovskite film with a gradient structural characteristic according to claim 1, wherein, in the precursor solution, a molar ratio of n-butyl ammonium to the second spacer cation is 1:0.01-0.3.

3. The two-dimensional Ruddlesden-Popper hybrid perovskite film with a gradient structural characteristic according to claim 2, wherein the precursor solution is a mixture of methylamine hydroiodide, hydroiodides of two spacer cations, lead iodide and an organic solvent, and the organic solvent is one of or a mixture of more than one of formamide, dimethyl sulfoxide, or N,N-dimethylformamide.

4. The two-dimensional Ruddlesden-Popper hybrid perovskite film with a gradient structural characteristic according to claim 3, wherein, in the precursor solution, a ratio of the lead iodide to the organic solvent is 50-800 mg:1 mL.

5. The two-dimensional Ruddlesden-Popper hybrid perovskite film with a gradient structural characteristic according to claim 3, wherein, in the precursor solution, a molar ratio of the hydroiodides of the two spacer cations:the methylamine hydroiodide:the lead iodide is 2:2:3 or 2:3:4 or 2:4:5.

6. The two-dimensional Ruddlesden-Popper hybrid perovskite film with a gradient structural characteristic according to claim 1, wherein, the depositing specifically comprises: spin-coating the precursor solution on a substrate to form a film, and annealing.

7. The two-dimensional Ruddlesden-Popper hybrid perovskite film with a gradient structural characteristic according to claim 6, wherein, during the spin-coating, a temperature of the substrate is 25-70° C., and a temperature of the precursor solution is the same as that of the substrate.

8. The two-dimensional Ruddlesden-Popper hybrid perovskite film with a gradient structural characteristic according to claim 6, wherein a temperature range for the annealing is 70-150° C., and a time range for the annealing is 5-20 min.

9. The two-dimensional Ruddlesden-Popper hybrid perovskite film with a gradient structural characteristic according to claim 6, wherein the substrate is an ITO glass substrate on which a PEDOT:PSS layer is spin-coated.

10. A method for preparing a two-dimensional Ruddlesden-Popper hybrid perovskite film with a gradient structural characteristic, the method comprising the following steps of:
firstly, preparing an ITO glass substrate on which a PEDOT:PSS layer is spin-coated;
subsequently, mixing hydroiodides of two spacer cations, methylamine hydroiodide and lead iodide with an organic solvent to obtain a precursor solution, wherein one of the two spacer cations is n-butyl ammonium, and a second spacer cation of the two spacer cations is phenylethyl ammonium, benzyl ammonium, t-butyl ammonium, imidazolyl ammonium, ethylpyridyl ammonium, or isobutyl ammonium, a molar ratio of the n-butyl ammonium to the second spacer cation is 1:0.01-0.3, a ratio of the lead iodide to the organic solvent is 50-800 mg: 1 mL, the organic solvent is one of or a mixture of more than one of formamide, dimethyl sulfoxide, or N,N-dimethylformamide, and a molar ratio of the hydroiodides of the two spacer cations:the methylamine hydroiodide:the lead iodide is 2:2:3 or 2:3:4 or 2:4:5; and
finally, spin-coating the precursor solution on the substrate to form a film, and annealing, wherein, during the spin-coating, a temperature of the substrate is 25-70° C., a temperature of the precursor solution used for the spin-coating is the same as that of the substrate, a temperature range for the annealing is 70-150° C., and a time range for the annealing is 5-20 min.
